(19) United States
(12) Patent Application Publication
(10) Pub. No.: US 2026/0005041 A1
(43) Pub. Date: Jan. 1, 2026

(54) GAS INJECTION SYSTEMS, REACTOR SYSTEMS INCLUDING GAS INJECTION SYSTEMS, AND METHODS FOR SUPPLYING A PROCESS GAS TO A REACTION CHAMBER

(71) Applicant: ASM IP Holding B.V., Almere (NL)

(72) Inventors: Chuwei Chen, Tempe, AZ (US); Wentao Wang, Chandler, AZ (US); Junwei Su, Chandler, AZ (US); Alexandros Demos, Scottsdale, AZ (US)

(21) Appl. No.: 19/250,178

(22) Filed: Jun. 26, 2025

Related U.S. Application Data
(60) Provisional application No. 63/666,063, filed on Jun. 28, 2024.

(51) Int. Cl. H01L 21/67

(52) U.S. Cl. CPC H01L 21/67069

(57) ABSTRACT

Gas injection systems, reactor systems including gas injection systems, and methods for supplying a process gas to a reaction chamber are disclosed. The gas injection systems disclosed include gas source assemblies coupled to gas distribution assemblies in which an etchant gas and a precursor gas are combined prior to injection into a reaction chamber.

### CROSS-REFERENCE TO RELATED APPLICATION(S)

This Application claims the benefit of U.S. Provisional Application 63/666,063 filed on June 28, 2024, the entire contents of which are incorporated herein by reference.

### FIELD

The present disclosure relates generally to the field of systems and apparatus employed in the manufacture of semiconductor devices and integrated circuits. More particular, the present disclosure relates to gas injection systems, reactor system including gas injection systems and associated methods.

### BACKGROUND

Semiconductor devices can be manufactured in a semiconductor processing system including one or more reaction chambers. Deposition gases, including precursors, dopants, and the like, can be injected into the reaction chamber to form a silicon-containing layer on a substrate disposed within the reaction chamber. In addition, further gases, such as etchants, can also be injected into the reaction chamber during the formation of the silicon- containing layer. For example, etchants can be employed in deposition-etch type processes, and/or in processes for cleaning the inner walls of the reaction chamber in which deposition occurs.

Conventional gas injection systems employed for the injection of precursor gases and etchant gases into a reaction chamber can comprise complex apparatus and assemblies which can require complicated and cost prohibitive fabrication process. In addition, conventional gas injection system may be impacted by poor flow stability which can have a detrimental effect on processes performed in a reaction chamber coupled to such conventional gas injection systems, Accordingly, improved gas injection systems and associated reactor systems are desirable for improve stability of gas injection into reaction chambers.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to gas injection systems, reactor systems including gas injection systems and associated methods for supplying a process gas to a reaction chamber. In particular embodiments the gas injection systems can comprise a gas distribution assembly which can pre-mix an etchant gas and a precursor gas prior to injection into a flange assembly coupled to a reaction chamber. In various embodiments the pre-mixing of the precursor gas and the etchant gas to form the process gas prior to injection into the flange assembly can result in less complex flange assemblies which can be easier to manufacture and maintain. In addition, the gas injection systems of the present disclosure can improve the stability of the process gas injected into a reaction chamber thereby improving the uniformity of processes performed with such gas injection systems. In addition, the gas injection systems of the present disclosure can improve the purity of the process gas injected into the reaction chamber by removing potential metallic contaminants from the wetted regions of the flange assembly.

Various embodiments of the disclosure provide a gas injection system comprising: a gas source assembly comprising a precursor source configured for supplying a precursor gas and an etchant source configured for supplying an etchant gas; a gas distribution assembly comprising: a plurality of precursor gas lines fluidly coupled to the precursor source; a plurality of etchant gas lines fluidly coupled to the etchant source; a plurality of dual manifolds, wherein each one of the plurality of the dual manifolds comprises a first input port fluidly coupled to one of the plurality of precursor gas lines, a second input port fluidly coupled to one of the plurality of etchant gas lines, and an output port configured to output a process gas comprising a mix of the precursor gas and the etchant gas; and a flange assembly comprising a plurality of gas channels formed within the flange assembly, wherein each one of the plurality of gas channels is fluidly coupled to the output port of one of the plurality of dual manifolds.

In some embodiments the flange assembly further comprises a plurality of gas expansion plenums formed within the flange assembly, wherein each of the one of plurality of gas expansion plenums is fluidly coupled to one of the plurality of gas channels.

In some embodiments the flange assembly further comprises a plurality of gas conduits formed within the flange assembly, wherein each one of the gas conduits comprises a conduit inlet fluidly coupled to one of the plurality of gas expansion plenums and a conduit outlet configured to inject the process gas into a reaction chamber.

In some embodiments each one of the plurality of gas conduits has a conduit width between 1.5 mm and 4 mm.

In some embodiments each one of the plurality of gas conduits has a conduit length between 1 mm and 10 mm.

In some embodiments the flange assembly comprises a flange housing, the flange housing comprising a front housing and a rear housing, wherein the front housing has a first coupling surface, and the rear housing has a second coupling surface, and the rear housing is coupled to the front housing by coupling the first coupling surface with the second coupling surface.

In some embodiments the front housing further comprising a rear surface comprising a plurality of concaved recesses and each one of the plurality of gas expansion plenums are at least partially defined by the second coupling surface and one of the plurality of concaved recesses.

In some embodiments the rear surface of the front housing further comprises a plurality of conduit surfaces where each of the conduit surfaces are recessed from the first coupling surface.

In some embodiments each one of the plurality of gas conduits are at least partially defined by the second coupling surface and one of the plurality of conduit surfaces.

In some embodiments the rear housing is mechanically affixed to the front housing by a series of threaded joints, wherein the series of threaded joint are inserted through a rear face of the rear housing and connect with the first coupling surface of the front housing, each of the threaded joints being positioned within non-wetted regions of the flange assembly.

Various additional embodiments of the disclosure provide a reactor system comprising: a reaction chamber; a flange assembly coupled to the reaction chamber, the flange assembly comprising: a flange housing comprising a front housing having a first coupling surface and a rear housing having a second coupling surface, wherein the rear housing is coupled to the front housing by coupling the first coupling surface to the second coupling surface; a plurality of gas channels formed within the front housing; a plurality of gas expansion plenums, each one of the plurality of gas expansion plenums being fluidly coupled to one of the plurality of gas channels, wherein each one of the plurality of gas expansion plenums is at least partially defined by the second coupling surface and one of a plurality of concaved recesses disposed in a rear surface of the front housing; and a plurality of gas conduits, each one of the plurality of gas conduits comprising a conduit inlet fluidly coupled to one of the plurality of gas expansion plenums and a conduit outlet configured to inject a process gas into the reaction chamber, wherein each one of the plurality of gas conduits is at least partially defined by the second coupling surface and one of a plurality of conduit surfaces disposed in the rear face of the front housing; and a gas injection system fluidly coupled to the flange assembly, the gas injection system comprising: a gas source assembly comprising a precursor source configured for supplying a precursor gas and an etchant source configured for supplying an etchant gas; and a gas distribution assembly comprising: a plurality of precursor gas lines fluidly coupled to the precursor source; a plurality of etchant gas lines fluidly coupled to the etchant source; and a plurality of dual manifold, wherein each of the plurality of dual manifolds comprises a first input port fluidly coupled to one of the plurality of precursor gas lines, a second input port fluidly coupled to one of the plurality of etchant gas lines, and an output port configured to output the process gas comprising the precursor gas and the etchant gas, wherein each of the plurality of gas channels of the flange assembly are fluidly coupled to the output port of one of the plurality of dual manifolds.

In some embodiments each one of the plurality of gas conduits has a conduit width between 1.5 mm and 4 mm.

In some embodiments each one of the plurality of gas conduits has a conduit length 1 mm and 10 mm.

In some embodiments the rear housing is mechanically affixed to the front housing by a series of threaded joints, wherein the series of threaded joint are inserted through a rear face of the rear housing and connect with the first coupling surface of the front housing, each of the threaded joints being positioned within non-wetted regions of the flange assembly.

Various additional embodiments of the disclosure provide a method for supplying a process gas to a reaction chamber, the methods comprising: supplying a precursor gas from a gas source assembly to a plurality of precursor gas lines; supplying an etchant gas from the gas source assembly to a plurality of etchant gas lines; mixing the precursor gas and the etchant gas within a plurality of dual manifolds to form the process gas, wherein each one of the plurality of dual manifolds comprises a first input port fluidly coupled to one of the plurality of precursor gas lines, a second input port fluidly coupled to one of the plurality of etchant gas lines; and an output port for outputting the process gas; supplying the process gas from the plurality of dual manifolds to a plurality of gas channels formed within a flange assembly, wherein the flange assembly is coupled to the reaction chamber; feeding the process gas from the plurality of gas channels to a plurality of gas expansion plenums formed within the flange assembly, wherein each one of the plurality of gas expansion plenums is fluidly coupled to one of the plurality of gas channels; feeding the process gas from the plurality of gas expansion plenums to a plurality of gas conduits, wherein each one of the plurality gas conduits is fluidly coupled to one of the plurality of gas expansion plenums; and injecting the process gas from the plurality of gas conduits into the reaction chamber.

In some embodiments the flange assembly comprises a flange housing, the flange housing comprising a front housing and a rear housing, wherein the front housing has a first coupling surface, and the rear housing has a second coupling surface, and the rear housing is affixed to the front housing by coupling the first coupling surface with the second coupling surface.

In some embodiments the front housing further comprising a rear surface comprising a plurality of concaved recesses and each one of the plurality of gas expansion plenums are at least partially defined by the second coupling surface and one of the plurality of concaved recesses.

In some embodiments the rear surface of the front housing further comprises a plurality of conduit surfaces where each one of the conduit surfaces are recessed from the first coupling surface and wherein each one of the plurality of gas conduits are at least partially defined by the second coupling surface and one of the plurality of conduit surfaces.

In some embodiments the process gas is injected into the reaction chamber at a process gas velocity between 30 and 70 meters per second.

In some embodiments the process gas is injected into the reaction chamber through the plurality of gas conduits, each of the plurality of gas conduits having a conduit width equal to or greater than 2 mm.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a cut-away side view of a reactor system in accordance with one or more embodiments of the disclosure.

FIG. 2 illustrates a gas injection system in accordance with one or more embodiments of the disclosure.

FIG. 3 illustrates a front view of a flange assembly including a portion of a gas distribution assembly in accordance with one or more embodiments of the disclosure.

FIG. 4 illustrates a cross sectional view of the front housing and the rear housing of the flange housing in accordance with one or more embodiments of the disclosure.

FIG. 5 illustrates a front view of a portion of a rear surface of the front housing in accordance with one or more embodiments of the disclosure.

FIG. 6 illustrates across sectional view of a flange housing in accordance with one or more embodiments of the disclosure.

FIG. 7 illustrates an expanded cross-sectional view of a flange housing in accordance with one or more embodiments of the disclosure.

FIG. 8 illustrates a method for supplying a process gas to a reaction chamber in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term substrate may refer to any underlying material or materials upon which a layer may be deposited. A substrate may include a bulk material, such as silicon (e.g., single-crystal silicon) or other semiconductor material, and may include one or more layers, such as native oxides or other layers, overlying or underlying the bulk material. The substrate may include various topologies, such as recesses, lines, and the like formed within or on at least a portion of a layer and/or bulk material of the substrate. A substrate may comprise one or more materials including, for example, silicon (Si), germanium (Ge), germanium tin (GeSn), silicon germanium (SiGe), silicon germanium tin (SiGeSn), silicon carbide (SiC), or a group Ill-V semiconductor material, such as, for example, gallium arsenide (GaAs), gallium phosphide (GaP), or gallium nitride (GaN). In some examples, the substrate may comprise one or more dielectric materials including, such as, oxides, nitrides, or oxynitrides. The substrate may comprise a silicon oxide (e.g., SiO2), a metal oxide (e.g., A1203), a silicon nitride (e.g., Si3N4), or a silicon oxynitride. The substrate may also comprise an engineered substrate where a surface semiconductor layer may be disposed over a bulk support with an intervening buried oxide (BOX) disposed therebetween. The substrate may contain one or more monocrystalline surfaces and/or one or more other surfaces that may comprise a non-monocrystalline surface, such as a polycrystalline surface and/or an amorphous surface. The substrate may include a layer comprising a metal, such as copper, cobalt, and the like.

In this disclosure, "gas" can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas.

The term "precursor" can refer to a compound that participates in the chemical reaction that produces another compound. The term "reactant" can be used interchangeably with the term precursor. The term "inert gas" can refer to a gas that does not take part in a chemical reaction and/or does not become a part of a layer to an appreciable extent. Exemplary inert gases include helium and argon and any combination thereof. In some cases, molecular nitrogen and/or hydrogen can be an inert gas. A carrier gas can be or include an inert gas.

Further, in this disclosure, any two numbers of a variable can constitute a workable range of the variable, and any ranges indicated may include or exclude the endpoints. Additionally, any values of variables indicated (regardless of whether they are indicated with "about" or not) may refer to precise values or approximate values and include equivalents, and may refer to average, median, representative, majority, or the like. Further, in this disclosure, the terms "including," "constituted by" and "having" can refer independently to "typically or broadly comprising," "comprising," "consisting essentially of," or "consisting of" in some embodiments. In this disclosure, any defined meanings do not necessarily exclude ordinary and customary meanings in some embodiments.

The present disclosure generally relates to gas injection systems, to reactor systems including a gas injection system, and to methods of using the gas injection systems and reactor systems. Gas injection systems and reactor systems including a gas injection system as described herein can be used to process substrates, such as semiconductor wafers, in gas- phase reactors. By way of examples, the systems and assemblies described herein can be used to form or grow epitaxial layers (e.g., doped semiconductor layers) on a surface of a substrate.

As set forth in more detail below, use of exemplary gas injection systems as described herein is advantageous, because it allows independent control of gas selection and flow rate at various locations within a reaction chamber. The independent control of gasses and flow rates can, in turn, allow independent tuning of film properties of films that are formed using a reactor system including the gas injection system. For example, an exemplary gas injection system can be used to independently tune resistivity and film thickness (or thickness uniformity) of, for example, epitaxially formed layers on a substrate. Additionally, or alternatively, exemplary gas injection systems can be used to compensate for gas flow variations, flow velocity, depletion rate variations, auto doping, or combinations thereof that otherwise occur within a reaction chamber of a reactor system. For example, the independent control of various gases can be used to compensate for edge effects and/or a rotating substrate, which might otherwise cause nonuniformity in one or more film properties.

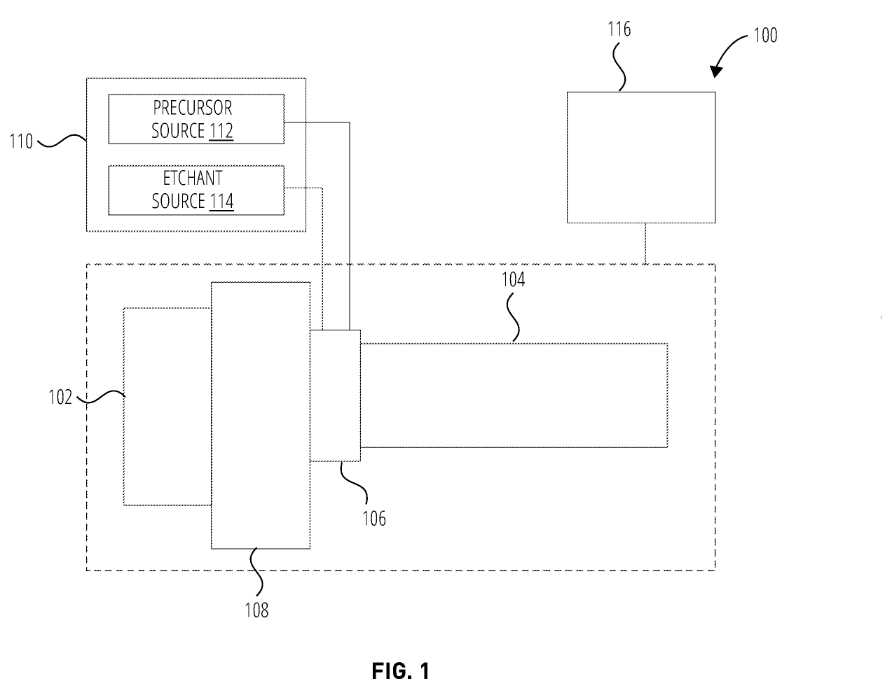

Turning now to the figures, FIG. 1 illustrates a cut-away side view of an exemplary reactor system 100. Reactor system 100 includes an optional substrate handling system 102, a reaction chamber 104, a gas injection system 106, and optionally a wall 108 disposed between reaction chamber 104 and substrate handling system 102. Reactor system 100 can also include a gas source assembly 110 which comprising at least a precursor source 112 and an etchant source 114. Reactor system 100 can also comprise an exhaust source 116. During operation of reactor system 100, substrates (not illustrated) can be transferred from, e.g., substrate handling system 102 to reaction chamber 104. Once substrate(s) are transferred to reaction chamber 104, one or more gases, such as precursors, etchants, dopants, carrier gasses, and/or purge gasses are introduced into reaction chamber 104 via gas injection system 106. Reactor system 100 can include any suitable reaction chamber 104, such as a horizontal flow, cold wall epitaxial reactor.

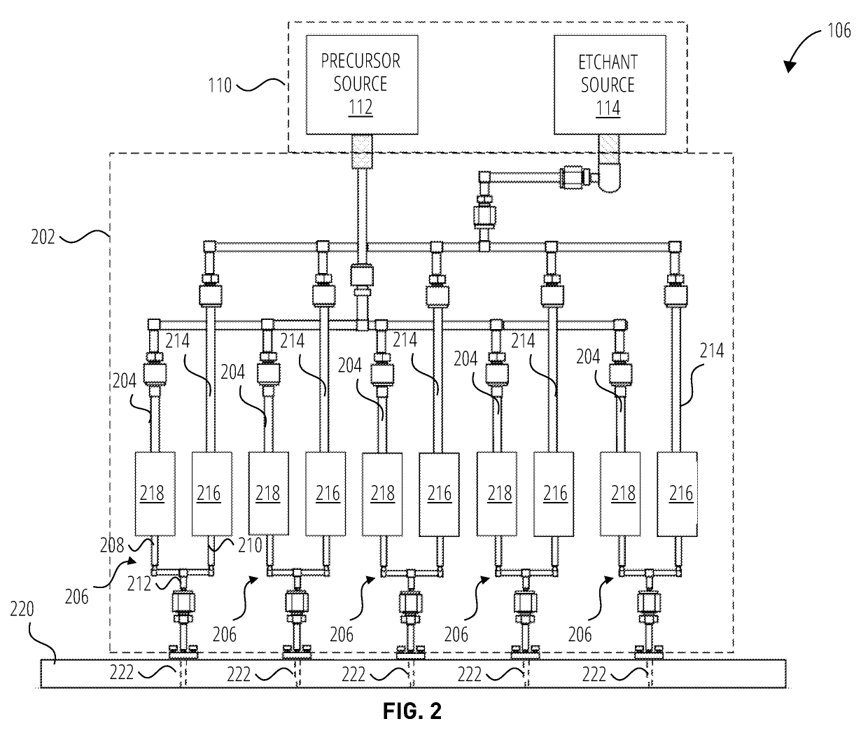

FIG. 2 illustrates a gas injection system 106 in accordance with various embodiments. The gas injection system 106 can comprise a gas source assembly 110. In various embodiments the gas source assembly 110 comprises at least two gas sources. For example, the gas source assembly 110 can comprise a precursor source 112 configured for supplying a precursor gas and an etchant source 114 configured for supplying an etchant gas. In various embodiments the precursor source 112 may supply one or more of trichlorosilane, dichlorosilane, silane, disilane, and trisilane. In various embodiments the etchant source 114 may supply one or more of chlorine, hydrochloride acid vapor and other etchants. The gas injection system 106 may also include additional sources, such as, for example, sources for supplying a carrier gas (e.g., argon, nitrogen, nitrogen), a purge gas (e.g., argon or nitrogen), or a dopant (e.g., As, P, C, Ge, and B).

In accordance with examples of the disclosure, gas injection system 106 can comprise a gas distribution assembly 202 comprising one or more (e.g., a plurality) of precursor gas lines 204 which can be coupled to the precursor source 112. In addition, the gas distribution assembly 202 can include one or more (e.g., a plurality) of etchant gas lines 214 which can be coupled to etchant source 114.

In accordance with examples of the disclosure, each one of the plurality of precursor gas lines 204 and each one of the plurality of etchant gas lines 214 can be coupled to a flow controller. In various embodiments each one of the plurality of the precursor gas lines 204 can be coupled to precursor flow controller 218 and each one of the plurality of etchant gas lines 214 can be coupled to an etchant flow controller 216. The flow controllers allow independent control of a flow (e.g., a flow rate) of respective gases to gas channels formed within a flange assembly 220. The precursor flow controllers 218 and the etchant flow controllers 216 can include any suitable automatic or manual valve that can control a flow rate of gas to a respective gas channel disposed within flange assembly 220. Although illustrated with two gas sources (112 and 114), gas injection systems 106 can include any suitable number of gas sources.

In accordance with examples of the disclosure, the gas distribution assembly 202 of gas injection system 106 can further comprises a plurality of manifolds configured for mixing the precursor gas and the etchant gas. In various embodiments the gas distribution assembly 202 may comprise a plurality of dual manifolds 206. In various embodiments each of the plurality of dual manifolds 206 comprises a device which comprises a first input port 208 configured for receiving a first gas from a first gas line and a second input port 210 configured for receiving a second gas from a second gas line. The dual manifold 206 further comprises an output port 212 configured for outputting a process gas comprising a gas mix of the first gas and the second gas. In various embodiments the gas distribution assembly 202 of the gas injection system 106 comprises a plurality of dual manifolds 206. In alternative embodiments dual manifolds 206 may be replaced with alternatives devices configured for receiving one or more gases, mixing the one or more gases, and outputting a gas mixture. In some embodiments each one of the plurality of dual manifolds 206 comprises a first input port 208 fluidly coupled to one of the plurality of precursor gas lines 204, a second input port 210 fluidly coupled to one of the plurality of etchant gas lines 214, and an output port 212 configured to output a process gas comprising a mix of both the precursor gas and the etchant gas.

In accordance with examples of the disclosure, the gas injection system 106 further comprises a flange assembly 220 (a portion of which is illustrated in FIG. 2). In such examples the flange assembly 220 comprising a plurality of gas channels 222 disposed within the flange housing of the flange assembly 220 (as described in greater detail below). In such examples each of the plurality of gas channels 222 within the flange assembly 220 are fluidly coupled to an output port 212 of one of the plurality of dual manifolds 206.

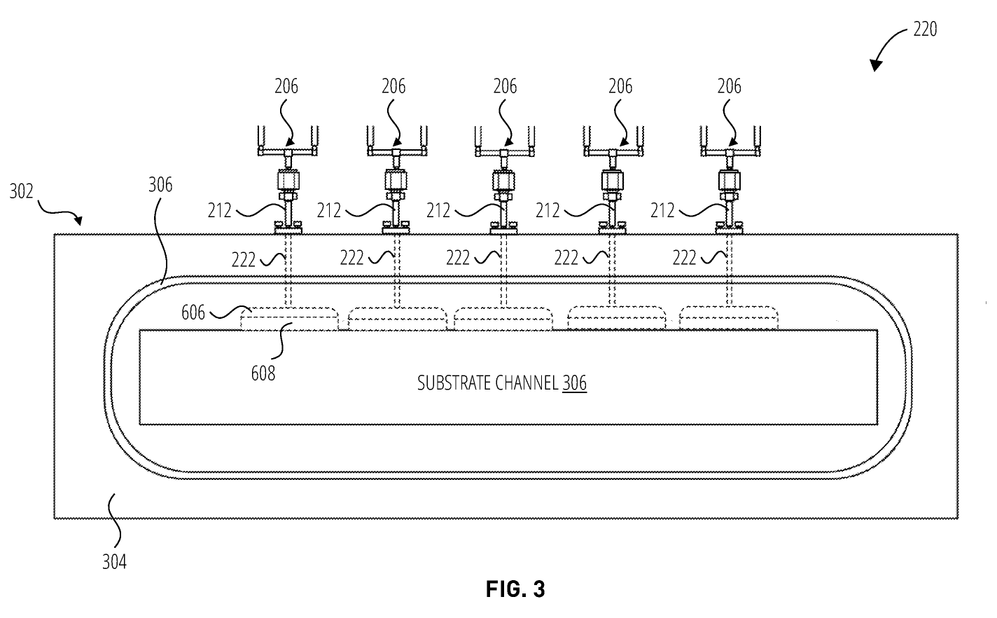

FIG. 3 illustrate the flange assembly 220 in greater detail. For example, FIG. 3 illustrates a front view of the flange assembly 220 including a portion of gas lines (of FIG. 2). It should be noted that the dashed elements in FIG. 3 represent the internal configuration of the flange assembly 220 and "front" as used in the context of the flange assembly refers to a structure or assembly facing a reaction chamber.

In accordance with examples of the disclosure and with reference to FIG. 3 the flange assembly 220 comprises a plurality of gas channels 222 formed within the flange assembly 220. In such examples each of the plurality of gas channels 222 formed within the flange assembly 220 are in fluid communication with an output port 212 of one of the plurality of dual manifolds 206.

In some embodiments the flange assembly 220 can comprise between 1 and 10 gas channels fed from between 1 and 10 output ports. In some embodiments the flange assembly 220 can comprise between 1 and 8 gas channels fed from between 1 and 8 output ports. In some embodiments the flange assembly 220 can comprise between 1 and 5 gas channels fed from between 1 and 5 output ports. In some embodiments the flange assembly 220 can comprise less than 10 gas channels and correspond output ports, less than 8 gas channels and correspond output ports, less than 5 gas channels and corresponding output ports, or less than 3 gas channels and corresponding output port.

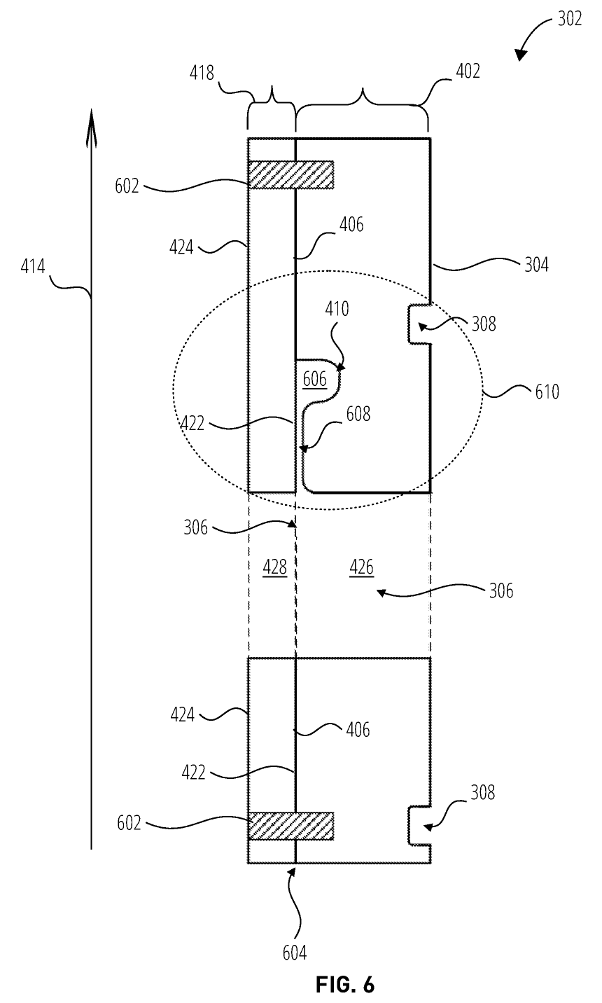

In accordance with examples of the disclosure, the flange assembly 220 can comprise a flange housing 302. In such examples the flange housing 302 can be formed of any suitable material, such as stainless steel, Hastelloy, and the like. The flange housing 302 can include a front face 304 constructed and arranged for coupling to a reaction chamber (such as reaction chamber 104 of FIG. 1), a rear face 424 (illustrated in FIG. 6) and a substrate channel 306 which extends through the flange housing 302 from the front face 304 to the rear face 424. The substrate channel 306 is sized to allow the insertion and extraction of substrates through the flange housing 302 for loading/unloading operations. The flange housing 302 also includes a groove 308 disposed in the front face 304 of the flange housing. The groove 308 surrounds the substrate channel 306 and is configured to receive a sealing element (not shown) such as an 0-ring, for example.

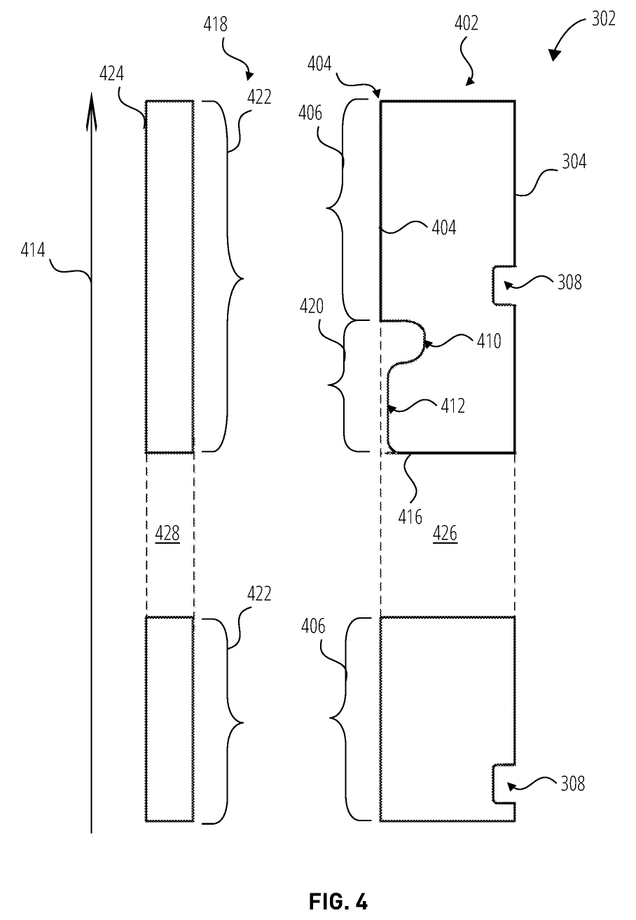

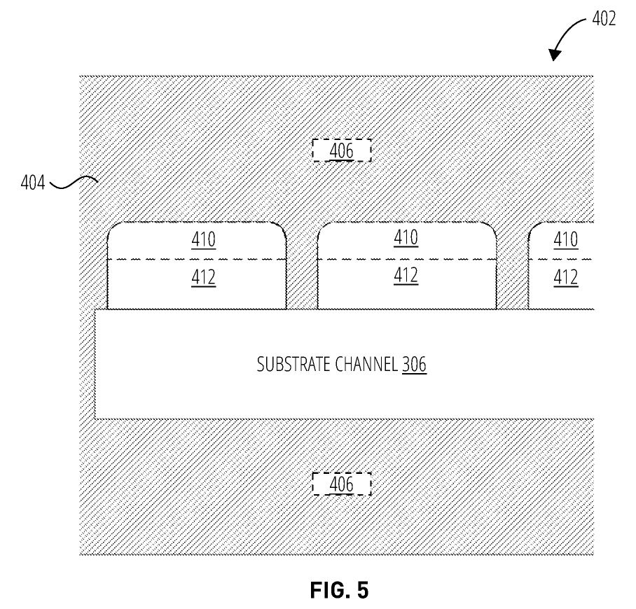

In accordance with examples of the disclosure, the flange housing 302 can comprise a front housing and a rear housing. FIG. 4 illustrates cross sectionals view of the front housing and the rear housing, FIG. 5 illustrates a front view of a portion of a rear surface of the front housing, and FIG. 6 illustrates a cross sectional view of the assembled flange housing.

In accordance with examples of the disclosure, the front housing 402 (FIG. 4) comprises a front face 304 of the flange assembly. The front face 304 comprises a groove 308 configured for housing a sealing element. The front housing 402 further comprises a rear surface 404. The rear surface 404 of the front housing 402 may comprise a first coupling surface 406 configured for coupling with the rear housing 418 of the flange housing 302 (as described in detail below). The first coupling surface 406 can extend along a first vertical plane, e.g., parallel to a longitudinal axis 414 of the housing. In various embodiments the rear surface 404 further comprises a recessed surface 420. In such embodiments the recessed surface 420 can include a concaved recess 410. A front view of the rear surface 404 (as shown in FIG. 5 ) illustrates that the rear surface 404 of the front housing 402 includes a plurality of concaved recesses 410, each of the plurality of concaved recess 410 being separated and isolated by a portion of the raised first coupling surface 406. In addition, the recessed surface 420 of front housing 402 comprises a conduit surface 412 (FIG. 4) which extends along a second vertical plane, e.g., parallel to a longitudinal axis 414 of the housing between the concaved recess 410 and the upper extent 416 of the front portion of the substrate channel 426. In some embodiments the conduit surface is recessed from the first coupling surface 406.FIG. 5 illustrates that the rear surface 404 of the front housing includes a plurality of conduit surfaces 412, each of the plurality of conduit surfaces 412 being separated and isolated by a portion of the raised first coupling surface 406 and being connected to each of the concaved recess 410.

In accordance with examples of the disclosure, the rear housing 418 comprises a second coupling surface 422, a rear face 424, and a rear portion of the substrate channel 428.

In accordance with examples of the disclosure, the flange housing 302 can be assembled by coupling (i.e., affixing) the rear housing to the front housing. FIG. 6 illustrates a cross sectional view of the assembled flange housing 302 comprising the front housing 402 and the rear housing 418 coupled to one another. As illustrated in FIG. 6 the first coupling surface 406 of the front housing 402 contacts the second coupling surface 422 of the rear housing 418 forming the flange housing 302.

In accordance with examples of the disclosure, the rear housing 418 may be mechanically affixed to the front housing 402 by a series of threaded joints 602 inserted from the rear face 424 of the rear housing 418. In such examples each of the threaded joints 602 can be insert into the first coupling surface 406 of the front housing 402. In some embodiments the threaded joints 602 are positioned within the flange housing 302 in non- wetted regions of the flange assembly 220. In other words, the series of threaded joint 602 do not come into contact with the process gas injected into the flange housing 302 thereby preventing contamination of the process gas injected into the flange assembly.

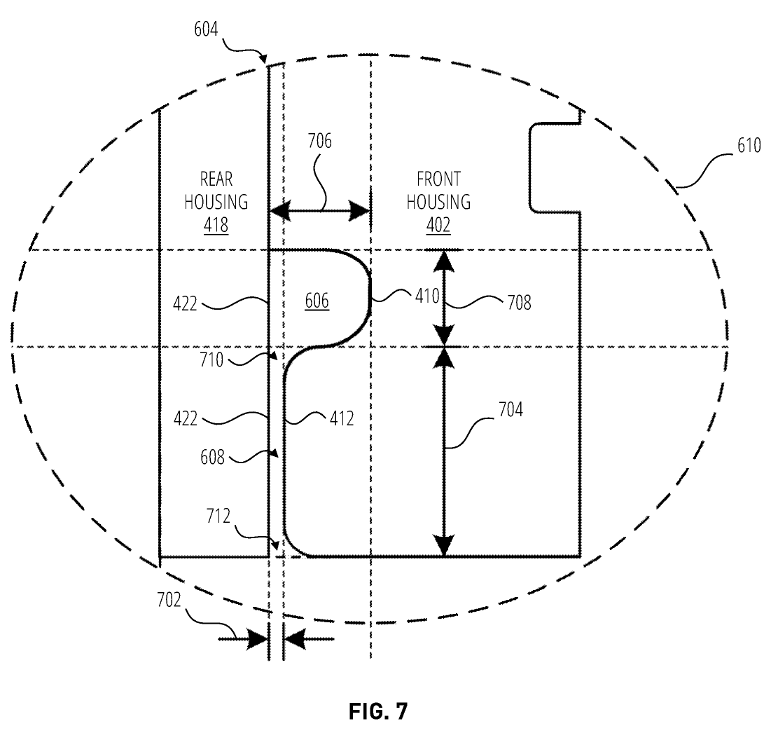

In accordance with examples of the disclosure, coupling the rear housing 418 with the front housing 402 forms an interface 604 disposed between the first coupling surface 406 and the second coupling surface 422. In various embodiments the coupling of the front housing 402 with the rear housing 418 forms a plurality of gas expansion plenums 606 and a plurality of gas conduits 608. In such embodiments the raised portion of the rear surface 406 (as illustrated in FIG. 5) can separate and isolate each one of the gas expansion plenums 606. In such embodiments the raised portion of the rear surface 406 (as illustrated in FIG. 5) can separate and isolate each one of the gas conduits 608. The region encircled by the dashed ellipse in FIG. 6 is expanded in FIG. 7 to further illustrate the formation of the gas expansion plenums and the gas conduits.

In accordance with examples of the disclosure and referring to FIG. 7, each one of the plurality of the gas expansion plenums 606 is at least partially defined by the second coupling surface 422 of the rear housing 418 and the concaved recess 410 disposed in the rear surface of the front housing 402. In various embodiments each one of the plurality of gas expansion plenums 606 formed in the flange assembly 220 is fluidly coupled to one of the plurality of gas channels 222, as illustrated in FIG. 3.

In some embodiments each one of the plurality of gas expansion plenums 606 can have a plenum width 706 between 4 mm and 40 mm, between 5 and 20 mm, between 6 and 10 mm. In some embodiments each one of the plurality of gas expansion plenums 606 can have a plenum width 706 equal to or less than 40 mm, 20 mm, 10 mm, 7 mm, or equal to or less than 4 mm. In some embodiments each one of the plurality of gas expansion plenums 606 can have a plenum width 706 equal to or greater than 4 mm, 10 mm, 20 mm, 30 mm, or equal to or greater than 40. mm.

In some embodiments each one of the plurality of gas expansion plenums 606 can have a plenum height 708 between 5 mm and 50 mm, between 10 and 25 mm, between 10 and 12 mm. In some embodiments each one of the plurality of gas expansion plenums 606 can have a plenum height 708 equal to or less than 50 mm, 25 mm, 12 mm, 10 mm, or equal to or less than 5 mm. In some embodiments each one of the plurality of gas expansion plenums 606 can have a plenum height 708 equal to or greater than 5 mm, 10 mm, 12 mm, 25 mm, or equal to or greater than 50. mm.

In additional embodiments the coupling of the front housing 402 with the rear housing 418 forms a plurality of gas conduits 608. In such embodiments each one of the plurality of gas conduits 608 (FIG. 7) is at least partially defined by the second coupling surface 422 of the rear housing 418 and the conduit surface 412 of the rear surface of the front housing 402. In various embodiments each one of the plurality of gas conduits 608 formed in the flange assembly 220 is fluidly coupled to one of the plurality of gas expansion plenums 606, as illustrated in FIG. 3 and FIG. 7. For example, each one of the plurality of gas conduits 608 (FIG. 7) can comprise a conduit inlet 710 fluidly coupled to one of the plurality of gas expansion plenums 606. In addition, each one of the plurality of gas conduits 608 can comprise a conduit outlet 712 configured to inject a process gas into a reaction chamber, such as reaction chamber 104 of FIG. 1.

In some embodiments each one of the plurality of gas conduits 608 can have a conduit width 702 between 1 mm and 5 mm, between 1.5 and 4 mm, o between 2 and 3 mm. In some embodiments each one of the plurality of gas conduits 608 can have a conduit width 702 equal to or less than 5 mm, 4 mm, 3 mm, 2 mm, or equal to or less than 1 mm. In some embodiments each one of the plurality of gas conduits 608 can have a conduit width 702 equal to or greater than 1 mm, 1.5 mm, 2 mm, 3 mm, or equal to or greater than 5. mm.

In some embodiments each one of the plurality of gas conduits 608 can have a conduit length 704 (i.e., the height of the conduit as illustrated in FIG. 7) between 0.5 mm and 12 mm, between 1 and 10 mm, between 2 and 6 mm. In some embodiments each one of the plurality of gas conduits 608 can have a conduit length 704 equal to or less than 12 mm, 10 mm, 6 mm, 3 mm, 2 mm, or equal to or less than 1 mm. In some embodiments each one of the plurality of gas conduits 608 can have a conduit length 704 equal to or greater than 1 mm, 2 mm, 6 mm, 10 mm, or equal to or greater than 12 mm.

The various embodiments of the disclosure also provide methods for supplying a process gas to a reaction chamber. In such embodiments the process gas can be supplied to the reaction chamber at a desired process gas velocity with a reduced variation in the peak velocity of the process gas.

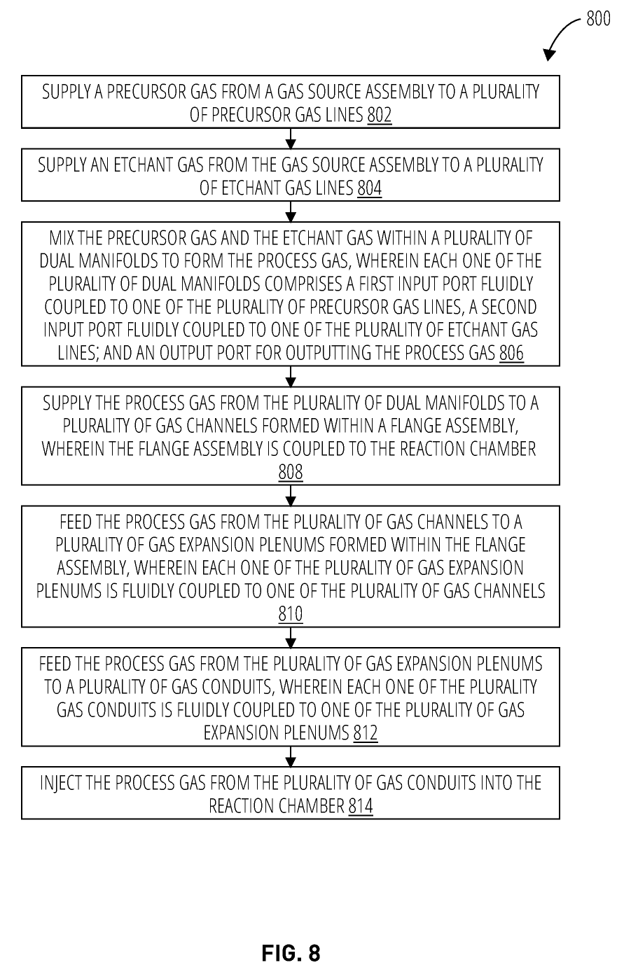

Turning again to the figures, FIG. 8 illustrates a method 800 for supplying a process gas to a reaction chamber. In accordance with examples of the disclosure, the method 800 can comprise supplying a precursor gas from a gas source assembly to a plurality of precursor gas lines (step 802) and supplying an etchant gas from the gas source assembly to a plurality of etchant gas lines (step 804).

In accordance with examples of the disclosure, the method 800 may further comprise mixing the precursor gas and the etchant gas within a plurality of dual manifolds to form the process gas, wherein each one of the plurality of dual manifolds comprises a first input port fluidly coupled to one of the plurality of precursor gas lines, a second input port fluidly coupled to one of the plurality of etchant gas lines; and an output port for outputting the process gas (step 806).

In accordance with examples of the disclosure, the method 800 may further comprise supplying the process gas from the plurality of dual manifolds to a plurality of gas channels formed within a flange assembly, wherein the flange assembly is coupled to the reaction chamber (step 808).

In accordance with examples of the disclosure, the method 800 may further comprise feeding the process gas from the plurality of gas channels to a plurality of gas expansion plenums formed within the flange assembly, wherein each one of the plurality of gas expansion plenums is fluidly coupled to one of the plurality of gas channels (step 810).

In accordance with examples of the disclosure, the method 800 may further comprise feeding the process gas from the plurality of gas expansion plenums to a plurality of gas conduits, wherein each one of the plurality gas conduits is fluidly coupled to one of the plurality of gas expansion plenums (step 812).

In accordance with examples of the disclosure, the method 800 may further comprise injecting the process gas from the plurality of gas conduits into the reaction chamber.

In some embodiments of method 800 the flange assembly may comprise a flange housing, the flange housing comprising a front housing and a rear housing, wherein the front housing has a first coupling surface, and the rear housing has a second coupling surface, and the rear housing is affixed to the front housing by coupling the first coupling surface with the second coupling surface.

In some embodiments of method 800 the front housing can further comprise a rear surface comprising a plurality of concaved recesses and each one of the plurality of gas expansion plenums can be at least partially defined by the second coupling surface and one of the plurality of concaved recesses.

In some embodiments of method 800 the rear surface of the front housing can further comprise a plurality of conduit surfaces wherein each one of the conduit surfaces are recessed from the first coupling surface and wherein each one of the plurality of gas conduits are at least partially defined by the second coupling surface and one of the plurality of conduit surfaces.

In some embodiments of method 800 the process gas can be injected into the reaction chamber at a process gas velocity between 20 and 200 meters per second (m/s), between 30 and 100 m/s, or between 30 and 70 m/s. In some embodiments of method 800 the process gas can be injected into the reaction chamber at a process gas velocity equal to or less than 200 m/s, 100 m/s, 70 m/s, 50 m/s, 30 m/s, or equal to or less than 10 m/s.

In some embodiments of method 800 the process gas can be injected into the reaction chamber at a process gas velocity between 30 and 70 meters per second. In some embodiments the process gas can be injected into the reaction chamber through a plurality of gas conduits, each one of the plurality of gas conduits having conduit width equal to or greater than 1 mm, 1.5 mm, 2 mm, 3 mm, or equal to or greater than 5. mm.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A gas injection system comprising: a gas source assembly comprising a precursor source configured for supplying a precursor gas and an etchant source configured for supplying an etchant gas; a gas distribution assembly comprising: a plurality of precursor gas lines fluidly coupled to the precursor source; a plurality of etchant gas lines fluidly coupled to the etchant source; a plurality of dual manifolds, wherein each one of the plurality of the dual manifolds comprises a first input port fluidly coupled to one of the plurality of precursor gas lines, a second input port fluidly coupled to one of the plurality of etchant gas lines, and an output port configured to output a process gas comprising a mix of the precursor gas and the etchant gas; and a flange assembly comprising a plurality of gas channels formed within the flange assembly, wherein each one of the plurality of gas channels is fluidly coupled to the output port of one of the plurality of dual manifolds.

2. The gas injection system of claim 1, wherein the flange assembly further comprises a plurality of gas expansion plenums formed within the flange assembly, wherein each of the one of plurality of gas expansion plenums is fluidly coupled to one of the plurality of gas channels.

3. The gas injection system of claim 2, wherein the flange assembly further comprises a plurality of gas conduits formed within the flange assembly, wherein each one of the gas conduits comprises a conduit inlet fluidly coupled to one of the plurality of gas expansion plenums and a conduit outlet configured to inject the process gas into a reaction chamber.

4. The gas injection system of claim 3, wherein each one of the plurality of gas conduits has a conduit width between 1.5 mm and 4 mm.

5. The gas injection system of claim 3, wherein each one of the plurality of gas conduits has a conduit length between 1 mm and 10 mm.

6. The gas injection system of claim 3, wherein the flange assembly comprises a flange housing, the flange housing comprising a front housing and a rear housing, wherein the front housing has a first coupling surface, and the rear housing has a second coupling surface, and the rear housing is coupled to the front housing by coupling the first coupling surface with the second coupling surface.

7. The gas injection system of claim 6, wherein the front housing further comprising a rear surface comprising a plurality of concaved recesses and each one of the plurality of gas expansion plenums are at least partially defined by the second coupling surface and one of the plurality of concaved recesses.

8. The gas injection system of claim 7, wherein the rear surface of the front housing further comprises a plurality of conduit surfaces where each of the conduit surfaces are recessed from the first coupling surface.

9. The gas injection system of claim 8, wherein each one of the plurality of gas conduits are at least partially defined by the second coupling surface and one of the plurality of conduit surfaces.

10. The gas injection system of claim 9, wherein the rear housing is mechanically affixed to the front housing by a series of threaded joints, wherein the series of threaded joint are inserted through a rear face of the rear housing and connect with the first coupling surface of the front housing, each of the threaded joints being positioned within non-wetted regions of the flange assembly.

11. A reactor system comprising: a reaction chamber; a flange assembly coupled to the reaction chamber, the flange assembly comprising:
a flange housing comprising a front housing having a first coupling surface and a rear housing having a second coupling surface, wherein the rear housing is coupled to the front housing by coupling the first coupling surface to the second coupling surface;
a plurality of gas channels formed within the front housing, a plurality of gas expansion plenums, each one of the plurality of gas expansion plenums being fluidly coupled to one of the plurality of gas channels, wherein each one of the plurality of gas expansion plenums is at least partially defined by the second coupling surface and one of a plurality of concaved recesses disposed in a rear surface of the front housing; and
a plurality of gas conduits, each one of the plurality of gas conduits comprising a conduit inlet fluidly coupled to one of the plurality of gas expansion plenums and a conduit outlet configured to inject a process gas into the reaction chamber, wherein each one of the plurality of gas conduits is at least partially defined by the second coupling surface and one of a plurality of conduit surfaces disposed in the rear surface of the front housing; and
a gas injection system fluidly coupled to the flange assembly, the gas injection system comprising: a gas source assembly comprising a precursor source configured for supplying a precursor gas and an etchant source configured for supplying an etchant gas; and a gas distribution assembly comprising: a plurality of precursor gas lines fluidly coupled to the precursor source; a plurality of etchant gas lines fluidly coupled to the etchant source; and a plurality of dual manifolds, wherein each one of the plurality of dual manifolds comprises a first input port fluidly coupled to one of the plurality of precursor gas lines, a second input port fluidly coupled to one of the plurality of etchant gas lines, and an output port configured to output the process gas
comprising the precursor gas and the etchant gas, wherein each of the plurality of gas channels of the flange assembly are fluidly coupled to the output port of one of the plurality of dual manifolds.

12. The reactor system of claim 11, wherein each one of the plurality of gas conduits has a conduit width between 1.5 mm and 4 mm.

13. The reactor system of claim 12, wherein each one of the plurality of gas conduits has a conduit length between 1 mm and 10 mm.

14. The reactor system of claim 13, wherein the rear housing is mechanically affixed to the front housing by a series of threaded joints, wherein the series of threaded joint are inserted through a rear face of the rear housing and connect with the first coupling surface of the front housing, each of the threaded joints being positioned within non-wetted regions of the flange assembly.

15. A method of supplying a process gas to a reaction chamber, the method comprising: supplying a precursor gas from a gas source assembly to a plurality of precursor gas lines; supplying an etchant gas from the gas source assembly to a plurality of etchant gas lines; mixing the precursor gas and the etchant gas within a plurality of dual manifolds to form the process gas, wherein each one of the plurality of dual manifolds comprises a first input port fluidly coupled to one of the plurality of precursor gas lines, a second input port fluidly coupled to one of the plurality of etchant gas lines; and an output port for outputting the process gas; supplying the process gas from the plurality of dual manifolds to a plurality of gas channels formed within a flange assembly, wherein the flange assembly is coupled to the reaction chamber;
feeding the process gas from the plurality of gas channels to a plurality of gas expansion plenums formed within the flange assembly, wherein each one of the plurality of gas expansion plenums is fluidly coupled to one of the plurality of gas channels;
feeding the process gas from the plurality of gas expansion plenums to a plurality of gas conduits, wherein each one of the plurality of gas conduits is fluidly coupled to one of the plurality of gas expansion plenums; and
injecting the process gas from the plurality of gas conduits into the reaction chamber.

16. The method of claim 15, wherein the flange assembly comprises a flange housing, the flange housing comprising a front housing and a rear housing, wherein the front housing has a first coupling surface, and the rear housing has a second coupling surface, and the rear housing is affixed to the front housing by coupling the first coupling surface with the second coupling surface.

17. The method of claim 16, wherein the front housing further comprising a rear surface comprising a plurality of concaved recesses and each one of the plurality of gas expansion plenums are at least partially defined by the second coupling surface and one of the plurality of concaved recesses.

18. The method of claim 17, wherein the rear surface of the front housing further comprises a plurality of conduit surfaces where each one of the conduit surfaces are recessed from the first coupling surface and wherein each one of the plurality of gas conduits are at least partially defined by the second coupling surface and one of the plurality of conduit surfaces.

19. The method of claim 15, wherein the process gas is injected into the reaction chamber at a process gas velocity between 30-70. meters per second.

20. The method of claim 19, wherein process gas is injected into the reaction chamber through the plurality of gas conduits, each of the plurality of gas conduits having a conduit width equal to or greater than 2 mm.
